(19) United States
(12) Patent Application Publication
(10) Pub. No.: US 2019/0032203 A1
(43) Pub. Date: Jan. 31, 2019

(54) METHOD FOR DEPOSITING AN IN SITU COATING ONTO THERMALLY AND CHEMICALLY LOADED COMPONENTS OF A FLUIDIZED BED REACTOR FOR PRODUCING HIGH-PURITY POLYSILICON

(71) Applicant: Wacker Chemie AG, Munich (DE)

(72) Inventor: Simon PEDRON, Burghausen (DE)

(73) Assignee: Wacker Chemie AG, Munich (DE)

(21) Appl. No.: 16/078,282

(22) PCT Filed: Feb. 23, 2017
(86) PCT No.: PCT/EP2017/054255

§ 371 Date: Aug. 21, 2018

(30) Foreign Application Priority Data
Feb. 26, 2016 (DE) 10 2016 203 082.5

(51) Int. Cl. C23C 16/44; C23C 16/24; C23C 16/34; C23C 16/442; B01J 8/18; B01J 19/02; C01B 33/03

(52) U.S. Cl. CPC C23C 16/4404; C23C 16/24; C23C 16/345; B01J 2219/0218; B01J 8/1872; B01J 19/02; C01B 33/03; C23C 16/442

(57) ABSTRACT

In situ coating of the reactor tube of a CVD fluidized bed reactor for producing granular polysilicon allows a wider selection of reactor tube materials to be used and provides granular polysilicon product of higher purity.

The invention relates to a process for depositing a coating for protecting thermally and chemically stressed components of a fluidized-bed reactor in processes for producing high-purity granular polycrystalline silicon.

Granular polycrystalline silicon is produced in a fluidized-bed reactor. This occurs by fluidization of silicon particles by means of a gas flow in a fluidized bed in the reactor tube of the fluidized-bed reactor, with the fluidized bed being heated to high temperatures by means of a heating device. As a result of introduction of a silicon-containing reaction gas, a pyrolysis reaction occurs at the hot particle surface. Elemental silicon here deposits on the silicon particles and the individual particles grow in diameter. The process can be operated continuously with all the associated advantages by regularly taking off grown particles and introducing smaller silicon particles as nucleus particles (seed). Such deposition processes and apparatuses for carrying them out are known, for example, from U.S. Pat. No. 4,786,477 A.

The reactor tube in the fluidized-bed reactor has to meet a variety of requirements. It has to be gastight, have a high mechanical stability, have a high purity and thus give low product contamination, in particular by metals, be chemically stable in the process atmosphere and be thermally stable at temperatures in the range from 600 to 1400° C.

Such a reactor tube generally consists of silica having a high purity. Other potential tube materials are not chemically stable in the process atmosphere (e.g. graphite) or due to the raw materials and sintering additives used have a high concentration of impurities (e.g. SSiC, NSiC, sintered silicon nitride, graphite, metallic materials). A reactor tube made of silica deforms at temperatures of >1150° C. To increase the stability, providing the reactor tube or other internal components of the fluidized-bed reactor with a coating is known. In this way, the abovementioned materials can also be made useable for the deposition process.

WO 13116146 A1 describes coating of internal components of a reactor with SiC and Si₃N₄. Here, liquid polymeric precursors (polysilazanes, polycarbosilanes) are applied at room temperature to the surface of the component to be coated or repaired. The actual ceramic layer is formed by heating the treated component in the reactor.

U.S. Pat. No. 4,668,493 A describes the in-situ infiltration of graphite components with liquid silicon to form SiC in a deposition reactor for high-purity polysilicon. Here, liquid silicon is deposited at high temperature from gaseous precursor gases in said reactor.

It is an object of the invention to provide a process which allows a coating for protecting thermally and chemically stressed components of the reactor to be applied in a fluidized-bed reactor for producing high-purity granular polysilicon.

The object is achieved by a process in which the reactor which is free of bed material or largely free of bed material is flushed with a reactive gas mixture at an average tube wall temperature of from 600 to 1400° C. for a period of from 1 hour to 8 days and at a pressure of from 1 to 15 bar abs and the surfaces of the reactor which have a temperature of more than 600° C. are thereby provided with an in-situ coating of Si and/or SiC and/or Si₃N₄ by means of a CVD process.

For the purposes of the invention, a reactor which is largely free of bed material means that the mass of Si particles in the reactor is less than 50% of the mass of Si particles which are present in the reactor during the steady-state deposition process.

The process is preferably carried out in a reactor which is free of bed material.

In the process of the invention, in-situ coating of the surfaces occurs from the gas phase by means of a CVD process, while in the processes according to the prior art a polymeric precursor is applied to the surfaces to be coated. It is in this way possible to achieve the advantages of wall coating by the process of the invention with a smaller outlay than in the case of known processes. Preference is given to the fluidized-bed reactor being charged with bed material immediately after the process of the invention and a process known from the prior art for producing granular polycrystalline silicon being carried out. The invention thus also provides a process for producing granular polycrystalline silicon, in which a coating is applied to thermally and chemically stressed components of the fluidized-bed reactor during running-in of the reactor.

In this process for producing granular polycrystalline silicon in a fluidized-bed reactor comprising a reactor tube and a heating device outside the reactor tube, the reactor tube is charged with a bed material in the form of silicon nucleus particles (seed) and the silicon nucleus particles are fluidized in the reactor by means of a gas flow to give a fluidized bed which is heated by means of the heating device and polycrystalline silicon is deposited on the hot silicon nucleus particles by means of pyrolysis as a result of introduction of a silicon-containing reaction gas into the fluidized bed and the granular polycrystalline silicon formed in this way is removed from the reactor tube. The process is characterized in that the reactor which is free of bed material or largely free of bed material is flushed with a reactive gas mixture at an average tube wall temperature of from 600 to 1400° C. for a period of from 1 hour to 8 days and at a pressure of from 1 to 15 bar abs and the surfaces of the reactor which have a temperature of more than 600° C. and come into contact with the reactive gas mixture are thereby provided with an in-situ coating of Si and/or SiC and/or Si₃N₄ by means of a CVD process.

The reactive gas mixture is preferably a mixture of one or more compounds of the formula (I) SiH₄₋ₓ—Clₓ (I) where 0≤x≤4 and a nitrogen source and/or a carrier gas selected from the group consisting of Ar or H₂ and/or an organic compound having from 1 to 10 carbon atoms, preferably an alkane of the formula (III) CₙH₂ₙ₊₂ (III) or a mixture of one or more compounds of the formula (II) RₓSiH_{y}Cl_{4-x-y} (II), where 1≤x≤4, 1≤y≤3 and x+y≤4 and R═CₙH₂ₙ₊₁ (n: integer from 1 to 10, preferably 1 to 5, particularly preferably n=1) and a carrier gas selected from the group consisting of Ar or H₂. x and y are integers.

A preferred composition of the reactive gas mixture is:
0-50% by volume of compound of the formula (I) SiH₄₋ₓClₓ, (I) where x: 0, 1, 2, 3 or 4
0-20% by volume of compound of the formula (III) CₙH₂ₙ₊₂, (III) where n: integer from 1 to 10, preferably from 1 to 5, particularly preferably 1
0-95% by volume of N₂
0-60% by volume of NH₃
0-50% by volume of N₂H₄
0-30% by volume of compound of the formula (II) RₓSiH_{y}Cl_{4-x-y} where 1≤x≤4 and 1≤y≤3 and x+y≤4, where x and y are integers and R is CₙH₂ₙ₊₁, where n: 1, 2, 3, 4, or 5
0-98% by volume of H₂
   where at least one compound of the formula (I) or (II) has to be present in a proportion by volume of >0.01%.

The compound of the formula (I) is preferably used in an amount of from 0.01 to 50% by volume, more preferably 0.1-10% by volume, particularly preferably 0.5-8% by volume.

In-situ coating preferably takes place at an absolute pressure of 1.5-8 bar, particularly preferably at 2-7 bar.

The process of the invention is preferably carried out during running-in of the fluidized-bed reactor for producing granular polycrystalline silicon. Furthermore, preference is given to carrying out the process during the renewed running-in after corroding of the fluidized-bed reactor, as described, for example, in US 20020081250 A1. In any case, the process is carried out before complete charging of the fluidized-bed reactor with bed material. The process of the invention as running-in process enables a layer of Si, SiC and/or Si₃N₄ of any thickness to be applied.

The process of the invention also makes it possible to repair the wall deposit as required without the reactor having to be taken out of operation. Recoating after a corroding process is also made possible in this way.

The surfaces of the reactor which have a temperature of more than 600° C. and are provided with an in-situ coating of Si, SiC and/or Si₃N₄ by means of a CVD process are preferably the surface of the reactor tube facing the reaction space and also the parts of the fluidized-bed reactor which are exposed to the process gas and the granular material, for example the expansion head inliner.

Coating of the surface of the reactor tube facing the reaction space is particularly preferred since the reactor tube has to maintain its mechanical stability and undamaged nature in order to maintain gastightness. For this reason, it is desirable for the coating processes for the reactor tube to take place in a temperature range which differs by not more than ±250° C., preferably ±150° C., particularly preferably ±100° C., from that in the steady-state fluidized-bed deposition process. The temperature is preferably measured at one or more places, optionally at different heights and angles around the circumference, on the outside of the reactor tube. Suitable measuring instruments are, in particular, pyrometers or thermocouples. The heating power of the heater or of the various heating elements is preferably regulated in such a way that one, more than one or preferably all measured temperature(s) vary within the abovementioned temperature range on the outside of the tube.

Silicon nitride also has advantageous properties: Si₃N₄ is electrically insulating, is present in high purity, has a high abrasion resistance and forms a diffusion barrier for metals. In the in-situ deposition of an Si₃N₄ layer, compounds of the formula (i) SiH₄₋ₓClₓ (0≤x≤4) (I) and as nitrogen source preferably N₂, alternatively or additionally NH₃ and/or N₂H₄ are used as precursors. x is preferably 0 or 3, and particularly preferably x=3. The deposition temperature is preferably from 600° C. to 1350° C. The deposition temperature is present at the surface to be coated on the inside of the tube. The higher x, the higher the deposition temperature has to be, but also the more homogeneous the Si₃N₄ layer produced. If monosilane SiH₄ is used, the deposition temperature is preferably 600-900° C., particularly preferably 650-850° C. If SiHCl₃ is used as silane, the deposition temperature is preferably 800-1200° C., particularly preferably 900-1150° C.

It is preferred but not necessary that the same silane/halide silane or the same (halo)silane mixture which is also used in the subsequent steady-state process known from the prior art for producing granular polycrystalline silicon is used as starting material.

Chlorosilanes, HCl and ammonium chloride are formed as by-products. The by-products are separated off in the offgas stream by distillation, adsorption, absorption or other thermal separation processes and are either recycled in the integrated facility or used otherwise.

The process is preferably carried out until a coating thickness of from 1 to 2500 μm, preferably from 5 to 800 μm, particularly preferably from 10 to 350 μm, of Si₃N₄ has been attained.

In the in-situ deposition of an Si layer, the gas mixture preferably consists of one or more compounds of the formula (I) SiH₄₋ₓClₓ (I) (0≤x≤4) and a carrier gas which is preferably H₂ or Ar. x is preferably 0 or 3, and particular preference is given to x=3. The deposition temperature is preferably from 600° C. to 1350° C. The higher x, the higher the deposition temperature has to be, but the more homogeneous the Si layer also becomes. If monosilane SiH₄ is used, the deposition temperature is preferably 600-900° C., particularly preferably 650-850° C. If SiHCl₃ is used as silane, the deposition temperature is preferably 800-1350° C., particularly preferably 900-1150° C.

It is preferred but not necessary that the same silane/halosilane or the same (halo)silane mixture which is also used in the subsequent steady-state process known from the prior art for producing granular polycrystalline silicon is used as starting material.

When graphite is used as main body of the reactor, Si which both penetrates into the porous main body and is also present on the component surface can react further to form SiC, with the properties of the main body being changed by the partial infiltration with SiC.

The compound of the formula (I) is preferably used in an amount of from 0.01 to 40% by volume, preferably 1-15% by volume, particularly preferably 2-10% by volume. The remainder is the carrier gas.

The process is preferably carried out until a coating thickness of from 1 to 200 000 μm, preferably from 100 to 10 000 μm, particularly preferably from 1000 to 6000 μm, of Si has been attained.

Silicon carbide is deposited from silanes/chlorosilanes which are substituted by hydrocarbon radicals and have the formula (II) RₓSiH_{y}Cl_{4-x-y} (II) where 1≤x≤4 and 1≤y≤3 and x+y≤4, where R is CₙH₂ₙ₊₁ and n is an integer from 1 to 5. Preference is given to using Ar or H₂ as carrier gas.

It is also possible to use a mixture of a compound of the formula (I) SiH₄₋ₓClₓ (I) (0≤x≤4), and an organic compound having from 1 to 10 carbon atoms, preferably an alkane of the formula (III) CₙH₂ₙ₊₂ (III) where n is an integer from 1 to 10, preferably from 1 to 5, particularly preferably 1, for example CH₄, C₂H₆ or C₃H₈ and one of the abovementioned carrier gases.

The compound of the formula (I) is preferably used in an amount in the range from 0.01 to 45% by volume, preferably 1-15% by volume, particularly preferably 2-10% by volume. The remainder is the carrier gas.

The process is preferably carried out until a coating thickness of from 1 to 2500 μm, preferably from 5 to 800 μm, particularly preferably from 10 to 350 μm, of SiC has been attained.

It is in principle possible to apply a mixed crystal layer by means of a combination of the various gases mentioned, e.g. an Si₃N₄/SiC mixed crystal layer by means of a feed gas mixture of a chlorosilane substituted by hydrocarbon radicals and N₂ or an Si/Si₃N₄ mixed crystal layer by means of a feed gas mixture of a silane, H₂ and N₂.

Depending on the material of the surfaces to be coated in the reactor, in particular in the reactor tube, various advantages are achieved when using the various coatings:

When the base material of the reactor tube is silicon carbide in the embodiments SSiC (sintered SiC), NSiC (nitride-bonded SiC), SiSiC (silicon-infiltrated SiC) or RBSiC (reaction-bonded SiC), an Si₃N₄ coating on the reactor tube serves as diffusion barrier since metallic impurities from the ceramic raw materials and sintering aids are present in the base material. An additional silicon coating can improve the product quality of the granular polycrystalline silicon produced in the reactor still further.

When the base material of the reactor tube is silicon nitride (sintered), an Si₃N₄ coating serves as diffusion barrier since metallic impurities from the ceramic raw materials and sintering aids are present in the base material. An additional silicon coating can improve the product quality of the granular polycrystalline silicon produced in the reactor still further.

When the base material of the reactor tube is fused silica, a silicon coating improves the product quality of the granular polycrystalline silicon produced in the reactor and stabilizes internal components mechanically.

When the base material of the reactor tube is graphite in the form of vibrated graphite or iso graphite, an Si₃N₄ coating makes the reaction tube gastight and serves as diffusion barrier for the base material and metals present therein. An additional silicon coating can improve the product quality of the granular polycrystalline silicon produced in the reactor still further.

An in-situ SiC coating also improves the product quality of the granular polycrystalline silicon produced in the reactor and additionally has a coefficient of thermal expansion similar to that of the base material when, for example, CTE-optimized iso graphite is used as base material.

When the base material of the reactor tube is sapphire glass, an Si₃N₄ coating acts as diffusion barrier. Furthermore, the silicon nitride layer protects the base material in the event of possible cyclically occurring corroding processes using HCl, which chemically decomposes Al₂O₃. Here too, an additional silicon coating can improve the product quality of the granular polycrystalline silicon produced in the reactor still further.

An in-situ SiC coating likewise improves the product quality of the granular polycrystalline silicon produced in the reactor and additionally has a coefficient of thermal expansion similar to that of the base material.

The reactor tube is possibly precoated with Si, Si₃N₄ or SiC. Layers of Si, Si₃N₄ or SiC which are present can be repaired by means of the process of the invention without the reactor having to be shut down.

The following examples serve to illustrate the invention further:

### EXAMPLE 1

A fluidized-bed reactor which is free of bed material and whose reactor tube consists of iso graphite is heated to the temperature at which the production of granular polycrystalline silicon is subsequently to be carried out (1300° C. at the outside of the reactor tube) and a gas mixture of N₂ and trichlorosilane (300 standard m³/h of N₂, 5 standard m³/h of trichlorosilane) is fed in for a period of 12 hours. This results in deposition of an Si₃N₄ layer having an average thickness of 150 μm on the inside of the reactor tube. The temperatures on the outside of the reactor tube are measured by means of two pyrometers and in each case kept constant to ±50° C. by adapting the heater power of the heaters. The reactor pressure during the coating process is 5 bar abs.

Subsequently, the flow of nitrogen is decreased. At the same temperature regulation, a layer of silicon having an average thickness of 250 μm is additionally applied over a period of 8 hours from a gas mixture of H₂ and trichlorosilane (200 standard m³/h of H₂, 10 standard m³/h of trichlorosilane) to the inside of the tube. The reactor pressure during this coating process is 3 bar abs.

During the further running-in process, during the course of which the reactor is first charged with granular silicon and the steady-state deposition conditions are subsequently set, the measured tube temperature is also kept constant to ±50° C. by adapting the heater power.

In the subsequent production of granular polycrystalline silicon, hydrogen is used as fluidizing gas. 17.5 mol % of the feed gas consists of trichlorosilane and the balance consists of hydrogen. The deposition takes place at a pressure of 3 bar (abs) and a fluidized-bed temperature of 1000° C. in a reactor tube having an internal diameter of 500 mm. Product is continuously taken off and the introduction of seed is regulated so that the Sauter diameter of the product is 1000±50 μm. The intermediate jacket is flushed with nitrogen.

The residence time of the reaction gas in the fluidized bed is 0.9 s.

### EXAMPLE 2

The steady-state granule deposition process as per Example 1 is carried out in a fluidized-bed reactor in which, in contrast to Example 1, the reactor tube consists of fused silica. In the steady-state deposition process, a temperature at the outside of the tube of 1400° C. is established in the reaction zone. At such temperatures, fused silica becomes soft under constant loading, so that the reactor tube would become deformed and no longer be sealed from the intermediate jacket.

For this reason, a supporting and at the same time highly pure layer of silicon is applied to the tube during the running-in process. During this, no bed or fluidized particles is/are present in the region which is to be coated. The tube temperature is kept constant at 1100±50° C. by adapting the heater power. Deformation of the tube during coating can be avoided in this way.

In the coating process, a gas mixture of H₂ and trichlorosilane (200 standard m³/h of H₂, 10 standard m³/h of trichlorosilane) is fed to the reactor over a period of 64 hours and a layer of silicon having an average thickness of 2500 μm is in this way applied to the inside of the tube. The coating is applied at an absolute pressure of 4 bar abs.

During the further running-in process, during the course of which the reactor is first charged with granular silicon and the steady-state deposition conditions are subsequently set, the measured tube temperature is kept constant to ±150° C. by adapting the heater power.

After a deposition time of 18 days, the entire silicon wall deposit in this reactor is corroded away in a corroding process using HCl. During this operation, a gas mixture of 80 standard m³/h of H₂ and 100 standard m³/h of HCl is fed to the reactor. Here too, the measured tube temperature is kept constant by adapting the reactor heating power. In this way, the tube is freed of the unwanted thick Si deposit above the fluidized bed. However, this also has the secondary effect that the Si deposit applied deliberately is corroded away.

After corroding, the coating process according to the invention as described above is carried out again. Subsequently, the steady-state deposition process for producing granular polycrystalline silicon is again carried out as described above.

1.-8. (canceled)

9. A process for coating thermally and chemically stressed components of a fluidized-bed reactor containing a reactor tube for producing granular polysilicon, comprising flushing the fluidized-bed reactor which is free of bed material or which contains a reduced amount of bed material as compared to the amount of bed material present during steady state production of granular polysilicon, with a reactive gas mixture at an average reactor tube wall temperature of from 600 to 1400° C. for a period of from 1 hour to 8 days and at a pressure of from 1 to 15 bar abs, and thereby providing surfaces of the reactor which have a temperature of more than 600° C. with an in-situ coating of Si and/or Si₃N₄ by means of a CVD process.

10. The process of claim 9, wherein the reactive gas mixture is a mixture of compounds of the formula SiH₄₋ₓClₓ (I) where 0≤x≤4 and a nitrogen source and/or a carrier gas selected from the group consisting of Ar or H₂ and/or an organic compound having from 1 to 10 carbon atoms; or is a mixture of one or more compounds of the formula RₓSiHyCl_{4-x-y}, (II) where 1≤x≤4, 1≤y≤3 and x+y≤4 and R═CₙH₂ₙ₊₁ (n=1-5) and a carrier gas selected from the group consisting of Ar, H₂, and mixtures thereof.

11. The process of claim 9, wherein the compound of the formula (I) or (II) is used in an amount of from 0.01 to 50% by volume.

12. The process of claim 9, wherein the compound of the formula (I) or (II) is used in an amount of from 0.01 to 10% by volume.

13. The process of claim 9, wherein coating takes place at a surface temperature which differs by not more than ±250° C., from the surface temperature in the steady-state fluidized-bed deposition process.

14. The process of claim 9, wherein coating takes place at a surface temperature which differs by not more than ±150° C., from the surface temperature in the steady-state fluidized-bed deposition process.

15. The process of claim 9, wherein coating takes place at a surface temperature which differs by not more than ±100° C., from the surface temperature in the steady-state fluidized-bed deposition process.

16. The process of claim 9, which takes place at an absolute pressure of 1.5-8 bar.

17. The process of claim 9, wherein the thermally and chemically stressed components of the fluidized-bed reactor are the surface of the reactor tube facing the reaction space and further parts of the fluidized-bed reactor which are exposed to process gas and granular material.

18. The process of claim 9, which is carried out to provide a coating thickness of from 1 to 200 000 μm.

19. A process for producing granular polycrystalline silicon, wherein a process of claim 9 is used during running-in of the reactor.
